(19) United States
(12) Patent Application Publication
(10) Pub. No.: US 2025/0157994 A1
(43) Pub. Date: May 15, 2025

(54) LIGHT-EMITTING DIODE FILM

(71) Applicant: O-Flex Co., Ltd., Yuseong-Gu (KR)

(72) Inventors: Hyun Jee YOO, Yuseong-gu (KR); Myung Seop KIM, Yuseong-gu (KR); Jung Ok MOON, Yuseong-gu (KR); Ryun Geun LIM, Yuseong-gu (KR); Se Ra KIM, Yuseong-gu (KR); Han Ki CHO, Yuseong-gu (KR)

(21) Appl. No.: 18/948,071

(22) Filed: Nov. 14, 2024

(30) Foreign Application Priority Data
Nov. 14, 2023 (KR) 10-2023-0157557

(51) Int. Cl. H01L 25/075; H01L 33/52; H01L 33/62

(52) U.S. Cl. CPC H01L 25/0753; H10H 20/852; H10H 20/857

(57) ABSTRACT

This disclosure relates to an LED film comprising: a substrate; an electrode layer formed on at least a portion of the substrate; solder formed on at least a portion of the electrode layer; a light-emitting diode (LED) positioned on the solder and connected to the electrode layer; a molding layer applied to cover the entire surface of the substrate, electrode layer, and LED; and a variable adhesive film located on the molding layer, wherein the LED film satisfies the following Equation 1:

$$1 * ( B + C ) \leq A \leq 5 * ( B + C ) \qquad [ Equation 1 ]$$

where A represents the height of the molding layer measured from the substrate, B represents the thickness of the solder, and C represents the thickness of the LED. The LED film of this disclosure provides excellent adhesion reliability and reworkability after attachment while protecting the LED and electrode.

### CROSS REFERENCE TO RELATED APPLICATION

The present application claims priority to Republic of Korea Patent Application No. 10-2023-0157557 filed on Nov. 14, 2023. The entire contents of the above-listed application are hereby incorporated by reference for all purposes.

### TECHNICAL FIELD

This disclosure relates to a light-emitting diode film.

### BACKGROUND TECHNOLOGY

As the information society progresses, the demand for display devices has increased in various forms. In response, research and usage of various display devices such as LCD (Liquid Crystal Display), PDP (Plasma Display Panel), ELD (Electroluminescent Display), VFD (Vacuum Fluorescent Display), OLED (Organic Light Emitting Diode), and LED (Light Emitting Diode) have become more widespread. Recently, display devices are being installed indoors and outdoors for advertising purposes. Transparent LED displays, in particular, can clearly show objects behind them when turned off, while displaying various digital signage content when the LEDs are turned on.

Among transparent LED displays, transparent LED films are display devices in which light-emitting diodes (hereinafter referred to as “LEDs”) are installed on a thin film as a light source. Transparent LED display films may include multiple LEDs and operate these LEDs according to external driving signals to display intended images. These transparent LED display films, made entirely of film, are thin, lightweight, and have a flexible structure.

Transparent LED display films can be attached to various surfaces, such as curved or flat surfaces, for different purposes. For attachment to various surfaces, transparent LED display films require high adhesion reliability. In the attachment process, if the position of the transparent LED display film is incorrectly set or impurities are mixed between the installation target and the film, re-releasability is required to allow the transparent adhesive film to be removed and reapplied from the installation object.

For the formation of an adhesive layer to attach the transparent LED display film to the target adherend surface, conventional transparent LED display films use a method involving punching the part of the sheet where the LED is positioned, aligning it after perforation, and attaching it, where the sheet has a layered structure with a pressure-sensitive adhesive (PSA) and a polyester layer for molding. This method has the disadvantage of a complex manufacturing process and lengthy production time. Furthermore, since the light source is located in a hole, it is vulnerable to impact, and if contaminants adhering to the hole come into contact with the metal pads or light source, defects can occur.

Prior Art Document 001 discloses a transparent light-emitting diode film, including a base, an electrode layer with at least one pattern formed on the base, pads formed on at least a part of the electrode layer, light-emitting diodes positioned on the pads, and an adhesive layer formed on at least another part of the electrode layer. The adhesive layer has an opening corresponding to the light-emitting diode (see FIG. 1). In Prior Art Document 001, the base includes a heat-resistant material to prevent state changes due to temperature when forming the transparent light-emitting diode film.

However, in Prior Art Document 001 (Korean Patent Publication No. 2017-0139924, published on Dec. 20, 2017), shows that the optical adhesive layer in the transparent light-emitting diode film is located only in the areas excluding the light-emitting diode, as shown in FIG. 1. An opening is formed in the area corresponding to the LED to mount the LED after the adhesive layer is laminated. In such a manufacturing process where an opening is formed, and the LED is then mounted, the complexity of the process steps and the LED film structure results in a high cost for transparent LED films. Additionally, when the protective layer of the transparent LED film is removed and adhered to the target adherend surface, impurities can easily enter the opening where the LED is mounted. In this case, impurities may adhere to the metal pad or light source, potentially leading to product damage and defects due to heating.

Moreover, since there is no adhesive layer at the position where the light-emitting diode chip such as LED chips is mounted, there is a limitation in adhesion reliability with the adherend surface of the installation target.

As shown in FIG. 2, the adhesive layer formed around the opening of a conventional transparent LED display film has a laminated structure of PSA and PET, but during the process of attaching the adhesive layer to the adherend surface after removing the release film, impurities are likely to enter the opening, and there is an issue where there is a limited adhesive surface present in the openings.

In an effort to address the above problems, Prior Art Document 002 (Korean Patent No. 10-2425807, registered on Jul. 22, 2022) attempted to solve the problem of contaminant ingress by covering the light source positioned in the through-hole with thermosetting liquid resin. Prior Art Document 002 includes a substrate with a front surface and a rear surface facing the front surface of the substrate; an electrode layer formed on the front surface of the substrate; a light source installed on the front surface of the substrate and connected to the electrode layer; a first resin layer attached to the front surface of the substrate, with a through-hole exposing at least part of the electrode layer and the light source to the outside; and a second resin covering at least part of the electrode layer exposed in the through-hole. The resin layer can be formed by pouring liquid resin onto the base, most of which is a thermosetting resin. However, when it undergoes the thermal curing process, shrinkage may cause the surface to become uneven, creating gaps that reduce the bonding area between the resin layer and the adherend surface, thereby decreasing bonding strength and adhesion. To prevent this, it is necessary to apply uniform pressure to the front surface during curing with a heat source to achieve flattening, which is cumbersome and has drawbacks. For example, a large and heavy apparatus is needed to apply hundreds of kilograms of force per square meter, and there is a risk of depth deformation of the film during the curing process.
(Prior Art Document 0001) Korean Patent Laid-Open Publication No. 2017-0139924 (published on Dec. 20, 2017)
(Prior Art Document 0001) Korean Registered Patent Publication No. 10-2425807 (registered on Jul. 22, 2022)

### SUMMARY

### Contents of the Disclosure

### Problems to be Solved

Therefore, this disclosure aims to address the problems of conventional technology mentioned above by applying a molding layer to the upper front surface of the electrode layer, solder, and light-emitting diode and by laminating a variable adhesive film on top of the molding layer. This provides a light-emitting diode film that protects the LED and electrode, has excellent adhesion reliability, and allows for easy reworking after attachment.

Additionally, this disclosure aims to reduce manufacturing costs by simplifying the structure and manufacturing process of the improved light-emitting diode film.

### Solution Means

This disclosure provides a light-emitting diode film, comprising: a substrate, an electrode layer formed on at least a portion of the substrate, solder formed on at least a portion of the electrode layer, a light-emitting diode located on the solder and connected to the electrode layer, a molding layer applied to cover the entire surface of the substrate, electrode layer, and light-emitting diode, and a variable adhesive film positioned on the molding layer, wherein the light-emitting diode film satisfies the following Equation 1:

$$1 * ( B + C ) \leq A \leq 5 * ( B + C ) \qquad [ Equation 1 ]$$

In this Equation, A represents the height of the molding layer measured from the substrate, B represents the thickness of the solder, and C represents the thickness of the light-emitting diode.

In one embodiment of this disclosure, the molding layer may have an adhesion strength of 100 gf/cm or more with respect to each of the substrate and the variable adhesive film.

In one embodiment of this disclosure, the Young's modulus of the molding layer may be from 0.05 to 50 MPa.

In one embodiment of this disclosure, the molding layer may be formed by curing a molding liquid with UV.

In one embodiment of this disclosure, the molding liquid may have a cure shrinkage rate of 13% or less.

In one embodiment of this disclosure, the viscosity of the molding liquid may be from 100 cps to 2,000 cps.

In one embodiment of this disclosure, the molding liquid may contain at least one oligomer or polymer selected from silicone acrylate, acrylate, urethane acrylate, urethane, butylene, isobutylene and rubber; and oligomer or polymer selected from derivatives thereof, and UV initiators; and additives.

In one embodiment of this disclosure, the molding liquid may further include inorganic scattering particles, organic scattering particles, light-absorbing particles, or a combination thereof

In one embodiment of this disclosure, the molding liquid may be solvent-free.

In one embodiment of this disclosure, the variable adhesive film may include a base film and a variable adhesive layer on the base film, and the base film may be positioned directly on the molding layer.

In one embodiment of this disclosure, the variable adhesive layer may be attached to the target adherend surface of the intended installation object.

In one embodiment of this disclosure, the variable adhesive layer may have an adhesion strength (A-value) of 1 or more with respect to the target adherend surface of the intended installation object, defined by the following Equation 2:

A=(A2−A1)/A1 Where: [Equation 2]

A1 is the adhesion strength (gf/inch) measured 30 minutes after attaching to the target adherend surface at room temperature, and

A2 is the adhesion strength (gf/inch) measured 1,000 hours after attaching to the target adherend surface at room temperature.

In one embodiment of this disclosure, the adhesion strength (A1) of the variable adhesive layer with respect to the target adherend surface may be 50 gf/in or less.

In one embodiment of this disclosure, the adhesion strength (A2) of the variable adhesive layer with respect to the target adherend surface may is more than 50 gf/in.

In one embodiment of this disclosure, the target adherend surface may be made of glass or plastic material.

In one embodiment of this disclosure, the variable adhesive layer may be a pressure-sensitive adhesive.

In one embodiment of this disclosure, a release film may be included on the variable adhesive layer.

In a further embodiment of this disclosure, the thickness of the variable adhesive layer may be from 50 to 150 μm.

In one embodiment of this disclosure, the substrate may have light-absorbing, light-blocking, or light-scattering functions.

In one embodiment of this disclosure, at least one layer of the base film and the variable adhesive layer in the variable adhesive film may have light-absorbing, light-blocking, or light-scattering function.

In one embodiment of this disclosure, the transmittance of the variable adhesive film may be from 30% to 80%.

In one embodiment of this disclosure, the protective film or protective coating layer may be further included on the lower part of the opposite side of the substrate where the electrode layer is formed.

In one embodiment of this disclosure, the protective film may include an adhesive layer, a base layer, and a protective coating layer, with the adhesive layer positioned facing the substrate.

In one embodiment of this disclosure, the protective coating layer may have light-absorbing, light-blocking, or light-scattering function.

In one embodiment of this disclosure, at least one layer of the adhesive layer, base layer, and protective coating layer may have light-absorbing, light-blocking, or light-scattering function.

In one embodiment of this disclosure, the light-emitting diode film may include a contrast-enhancing layer directly beneath the opposite side of the substrate on which the electrode layer is formed.

In one embodiment of this disclosure, the light-emitting diode film may include a construction protection film on the lowest part of the substrate.

In a further embodiment of this disclosure, after a light resistance test, the yellow index (b*) of the light-emitting diode film may be Δ5 or less.

### Effects of the Disclosure

This disclosure provides a light-emitting diode (LED) film capable of protecting the LED and electrode from external forces, with excellent adhesion reliability and reworkability after attachment, thereby improving attachment applicability.

Moreover, this disclosure simplifies the manufacturing process of the LED film, allowing for a reduction in production costs.

### BRIEF DESCRIPTION OF THE DRAWINGS

FIG. 1 and FIG. 2 show cross-sectional views of a conventional light-emitting diode film.

FIG. 3 and FIG. 4 depict cross-sectional views of an embodiment of the light-emitting diode film according to this disclosure.

FIG. 5 illustrates an example of the LED film of this disclosure attached to the target adherend surface of the intended installation object

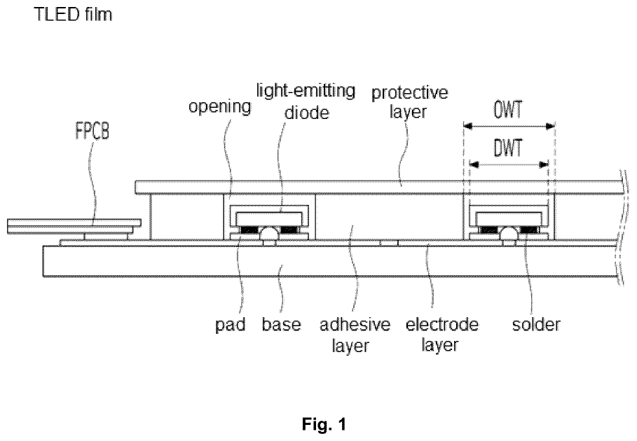

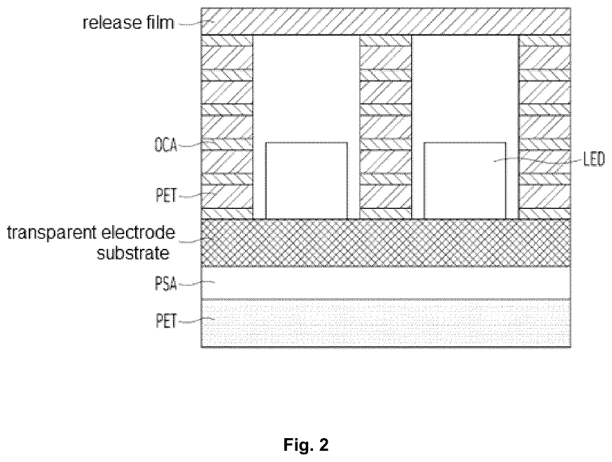

### DETAILED DESCRIPTION OF THE DISCLOSURE FOR IMPLEMENTATION

Hereinafter, embodiments of this disclosure will be described in detail with reference to the attached drawings, so that those skilled in the art can easily implement the disclosure. However, the disclosure may be embodied in various forms and is not limited to the embodiments described here. In the drawings, parts unrelated to the description have been omitted for clarity, and similar reference numbers are used for similar parts throughout the specification.

In the specification, terms like “connected,” “attached,” or “adhesive” may mean both direct connection and indirect electrical connection with other elements interposed between them.

In the specification, terms like “on,” “above,” “upper,” “below,” “under,” and “lower” may mean a relative spatial relationship for the ease of understanding, as shown in the drawings.

In the specification, the term “light-emitting diode” refers to a basic semiconductor diode structure (e.g., LED chip), which may include organic, inorganic, or quantum dot LED chips or devices.

The term “intended installation target” refers to the target or object where the LED film of this disclosure is ultimately attached, such as outdoor walls, indoor ceilings, walls, sides of transportation means, windows, banners, posters, and flyers, but is not limited to these.

The LED film according to this disclosure is attached to the “target adherend surface” or “adhesive surface” of the intended installation target. In the entire specification, terms like “adherend surface,” “adhesive surface,” “adhesive side,” or “target adherend surface” are used interchangeably to mean the same thing.

Additionally, materials for the target adherend surface include glass or plastic with no bumps or high flatness. Plastics may include polymethyl methacrylate (PMMA), polycarbonate (PC), acrylonitrile butadiene styrene (ABS), polyamide (PA), polypropylene (PP), polyethylene (PE), polyvinyl chloride (PVC), etc.

In the entire specification of this disclosure, when a component is described as “comprising” or “including” a certain part, this is not intended to exclude other components unless explicitly stated otherwise; rather, it indicates that additional components may be included.

All terms used in this specification (including technical and scientific terms) should be interpreted as having the same meaning as commonly understood by a person skilled in the relevant field, unless otherwise defined. Additionally, terms used in this specification should be interpreted consistently with their meanings in this document and the related technical field, and they should not be construed in an idealized or overly formal manner unless explicitly defined otherwise.

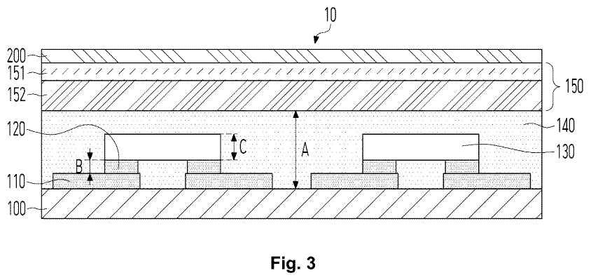

As shown in FIG. 3, this disclosure comprises: a substrate (100); an electrode layer (110) formed on at least a part of the substrate (100); solder (120) formed on at least a portion of the electrode layer (110); a light-emitting diode (130) located on the solder (120) and connected to the electrode layer (110); a molding layer (140) applied to the entire surface of the substrate (100), electrode layer (110), and light-emitting diode (130); and a variable adhesive film (150) positioned on the molding layer (140), where the light-emitting diode (130) film satisfies the following Equation 1:

$$1 * ( B + C ) \leq A \leq 5 * ( B + C ) \qquad [ Equation 1 ]$$

Here, A represents the height of the molding layer measured from the substrate, B is the thickness of the solder, and C is the thickness of the light-emitting diode.

For the light-emitting diode film (10) according to this disclosure to ensure excellent adhesive reliability with the target adherend surface of the intended installation object, the thickness (A) of the molding layer (140) should be equal to or greater than the combined thicknesses of the solder thickness (B) and light-emitting diode thickness (C). If the thickness (A) of the molding layer (140) is less than that of the LED chip, there is a high chance of air bubbles forming and being trapped during the lamination process of the variable adhesive film (150), which can cause visual distortion during installation, thus reducing aesthetic functionality. Conversely, if the thickness (A) of the molding layer (140) is more than five times the combined thicknesses of the solder (120) thickness (B) and light-emitting diode (130) thickness (C), the flexibility and elasticity of the light-emitting diode film (10) decrease, the film thickness increases, and durability is reduced when applied to curved adherend surfaces of the installation object. Additionally, light diffusion issues can intensify when the light-emitting diode film (10) is in operation.

As shown in FIG. 3, the molding layer (140) is applied to cover the entire surface of the substrate (100), electrode layer (110), solder, and light-emitting diode (130). The molding layer (140) is applied on the substrate (100) to cover the entire mounted LED chip, protecting the LED chip from physical external forces and preventing impurities from entering the LED chip. Additionally, the manufacturing process of the light-emitting diode film (10) according to this disclosure is straightforward and simple, reducing manufacturing costs.

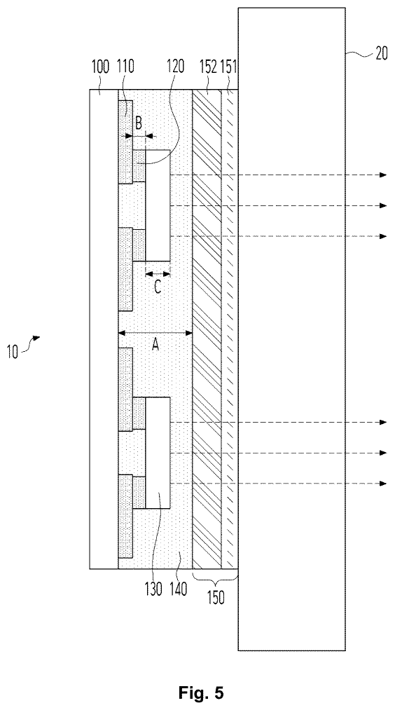

A variable adhesive film (150) is positioned on the molding layer (140). This variable adhesive film (150) may include a base film (152) and a variable adhesive layer on the base film (152). In this case, the base film (152) is directly positioned on and attached to the molding layer (140), and the variable adhesive layer (151) on the base film (152) is attached to the target adherend surface of the intended installation object. The base film (152) protects the electrode layer (110), solder (120), and light-emitting diode (130) from external forces, while the variable adhesive layer (151) provides excellent adhesive reliability and reworkability (see FIG. 5).

In this disclosure, one side of the molding layer (140) is attached to the substrate (100), while the other side is attached to the variable adhesive film (150) positioned above. The molding layer (140) has an adhesive strength of 100 gf/cm or more with respect to each of the substrate (100) and the variable adhesive film (150). Due to this high adhesive strength, the molding layer (140) protects the LED and electrode and exhibits excellent durability.

The Young's modulus of the molding layer (140) is from 0.05 MPa to 50 MPa, preferably from 0.05 to 30 MPa, and more preferably from 0.08 to 20 MPa. If the Young's modulus of the molding layer (140) is more than 50 MPa, flexibility, elasticity, and adhesive installation characteristics are reduced, while a Young's modulus is less than 0.05 MPa may expose the metal wiring, LED, and other components located on the lower part of the molding layer (140) to physical damage upon external impact.

The molding layer (140) may be formed by curing a molding liquid with UV, and the molding liquid is applied so that the cured molding layer (140) satisfies the following Equation 1:

$$1 * ( B + C ) \leq A \leq 5 * ( B + C ) \qquad [ Equation 1 ]$$

Here, A is the height of the molding layer measured from the substrate, B is the thickness of the solder, and C is the thickness of the light-emitting diode. Within this thickness range, the molding layer (140) exhibits high transparency and low curing shrinkage, improving flattening and adhesion to the LED chip, while providing excellent durability and adhesion on curved surfaces.

The curing shrinkage rate of the molding liquid is 13% or less when UV-cured, preferably 10% or less. A high curing shrinkage rate of the molding liquid may result in reduced adhesion, visual distortion due to level differences between the LED location and voids, and warping. Therefore, it is preferable for the curing shrinkage rate of the molding liquid to be 13% or less. The molding liquid in this disclosure, with low curing shrinkage, prevents deviations in thickness around the LED light source area and peripheral areas, avoiding optical distortion and detachment defects in a ring shape on the adherend surface when the light-emitting diode film (10) is applied. In this disclosure, the molding liquid provides a molding layer (140) with excellent surface flattening and high adhesive reliability on the entire surface of the substrate (100), where the electrode layer (110), solder (120), and light-emitting diode (130) are formed.

The viscosity of the molding liquid is from 100 cps to 2,000 cps at 23° C. before curing, and preferably from 100 to 1500 cps. Within this range, the coating thickness of the molding layer (140) does not become excessively thick and can be controlled to the desired thickness.

The molding layer (140) may be formed of a transparent material to allow easy light transmission. Preferably, it may have a transmittance of 80% or higher, like optical clear resin (OCR), which enhances visibility by increasing transmittance through low-reflective properties.

The molding liquid can be produced using an optically transparent adhesive resin composition to form optical clear resin (OCR). This optically transparent resin adhesive composition may include at least one oligomer or polymer selected from silicone acrylate, acrylate, urethane acrylate, urethane, butylene, isobutylene and rubber; and oligomer or polymer selected from derivatives thereof, and UV initiators; and additives. Below, we will describe the molding liquid in more detail by components, but it is not limited to these and may use other optically transparent resin compositions widely known for OCR production.

The weight-average molecular weight of the oligomer or polymer may be from about 5,000 to 300,000 g/mol.

### Acrylate Oligomer

The acrylate oligomer may include at least one oligomer selected from a group consisting of methyl methacrylate, urethane acrylate, epoxy acrylate, silicone acrylate, ethylhexyl acrylate, butyl acrylate, ethyl acrylate, isobornyl acrylate, cyclohexyl methacrylate, glycidyl methacrylate, glycidyl acrylate, behenyl acrylate, ethyl acrylate, lauryl acrylate, stearyl acrylate, acrylic acid, hydroxyethyl acrylate, hydroxybutyl acrylate, hydroxyethyl methacrylate, phenoxy acrylate, methyl acrylate, hexanediol diacrylate, and combinations thereof, but it is not limited to these, but preferably may be a urethane acrylate oligomer.

The acrylate resin may be included in an amount from 20 to 80 wt % relative to the total weight of the molding liquid. If the acrylate resin is included in an amount less than 20 wt %, the cure shrinkage rate of the molding layer may increase, while if the acrylate resin is included in an amount more than 80 wt % may decrease the durability of the molding layer.

The weight-average molecular weight of the acrylate resin may be from about 5,000 to 300,000 g/mol.

### Isobutylene Oligomer

The isobutylene oligomer may include an oligomer solely based on isobutylene monomer, an oligomer of isobutylene monomer with other polymerizable monomers, or mixtures thereof. Examples include oligomers containing monomers of 1-butene, 2-butene, isoprene, styrene, or butadiene.

The cured resin containing the isobutylene oligomer has very low polarity, is transparent, and is minimally affected by corrosion, thereby providing excellent moisture barrier properties, durability, reliability, and optical characteristics.

Examples of the isobutylene oligomer include oligomers of isobutylene and isoprene, oligomers of isoprene and styrene, oligomers of butadiene and styrene, and oligomers of isoprene, butadiene, and styrene, oligomers of polyisoprene, polybutadiene or isoprene, and styrene, or oligomers of isoprene and styrene, oligomers of butadiene and styrene, or oligomers of isoprene, butadiene, and styrene.

The isobutylene polymer may be included in an amount from 10 to 60 wt % relative to the total weight of the molding liquid.

### Rubber

The rubber may have functional groups such as hydroxyl or carboxyl groups at its terminal ends. For example, a polydiene with terminal hydroxyl or carboxyl groups may be used as the rubber component. Examples include compounds with a polyisoprene or polybutadiene backbone or styrene-butadiene backbone, ethylene-propylene copolymer (EPM) or ethylene-propylene-diene terpolymer (EPDM), but are not limited to these.

The weight-average molecular weight of the rubber may be selected within a range that does not impair the purpose of this application, for example, about 1,000 to 200,000 g/mol, about 1,000 to 150,000 g/mol, or about 2,000 to 100,000 g/mol.

The rubber may be included in an amount from 10 to 60 wt % relative to the total weight of the molding liquid.

### Acrylate Monomer

The optically transparent resin adhesive composition may additionally include an acrylate monomer.

This helps control viscosity by diluting the oligomer or polymer of macromolecule, and it provides required properties such as modulus, adhesion, and polarity to control whitening that may occur under high temperature and humidity tests. Both monofunctional and multifunctional acrylate monomers can be used. Using a UV curing reaction, the shrinkage rate, curing reaction speed, and durability of the molding layer can be controlled.

The acrylate monomer may be included in an amount from 20 to 90 wt % relative to the total molding liquid weight, preferably from 20 to 80 wt %, and more preferably from 30 to 70 wt %. If included in an amount less than 30 wt %, it becomes difficult to control the viscosity of the composition, while if included in an amount more than 70 wt %, it becomes challenging to control the curing shrinkage and curing reaction speed. Any structure may be applied as long as it is compatible with the oligomer or polymer used and satisfies the required properties.

### Photoinitiator

The photoinitiator generates active radicals when irradiated with ultraviolet light in a specific wavelength range, initiating a photopolymerization reaction with reactive acrylate oligomers or monomers. The photoinitiator may be a ketone-based or phosphine-based photoinitiator.

Examples of ketone-based photoinitiators include diphenyl(2,4,6-trimethylbenzoyl) phosphine oxide (TPO), 2-isopropylthioxanthone (ITX), 1-hydroxy-cyclohexyl-phenyl-ketone, 2-hydroxy-2-methyl-1-phenyl-1-propanone, and 2-methyl-1-[4-(methylthio)phenyl]-2-(4-morpholinyl)-1-propanone, among others, but are not limited to these.

The photoinitiator may be included in an amount from 0.01 to 2 wt % relative to the total weight of the molding liquid.

### Additives

The additives may include optional, commonly used additives such as reactive diluents, scattering agents, adhesion promoters, interface control agents, fillers, coupling agents, silanes, wetting agents, plasticizers, release agents, crosslinkers, catalysts, curing agents, wetting agents, UV stabilizers, thermal stabilizers, and corrosion inhibitors. The molding liquid may also contain other solvents as additives, although a solvent-free formulation is preferred. The reactive diluent and plasticizer can each be included in an amount from 1 to 10 wt % relative to the total molding liquid, while the combined total of other additives may be included in an amount from 0.01 to 5 wt % relative to the total molding liquid.

Solvents, which are volatile organic compounds, pose health risks and environmental pollution issues. Additionally, conventional processes using drying ovens for solvent evaporation reduce the productivity of the molding liquid. However, the solvent-free molding liquid of this disclosure addresses toxicity and environmental pollution concerns while also improving productivity by eliminating the drying process required for solvent evaporation. Additionally, since shrinkage due to solvent evaporation does not occur, it has the effect of reducing the cure shrinkage rate of the molding layer.

In one embodiment of this disclosure, the molding liquid may include inorganic or organic dyes and pigments to provide contrast improvement and optical properties. Examples of scattering agents include inorganic scattering particles such as SiO₂, TiO₂, ZrO₂, organic scattering particles, light-absorbing particles, or combinations thereof.

In one embodiment of this disclosure, the variable adhesive film (150) positioned on the molding layer (140) adheres to the adherend surface of the intended installation object, allowing the light-emitting diode film to be installed on intended installation object.

In one embodiment of the disclosure, the variable adhesive film (150) may include a base film (152) and a variable adhesive layer (151) on the base film (152). At this time, the base film (152) is directly positioned on and attached to the molding layer (140), and the variable adhesive layer (151) located on the base film (152) is attached to the target adherend surface of the intended installation object.

In one embodiment of the disclosure, the variable adhesive layer (151) of the variable adhesive film (150) satisfies an A-value of 1 or more with respect to the adherend surface, as defined by the following Equation 2:

$$A = ( A 2 - A 1 ) / A 1 \qquad [ Equation 2 ]$$

A1: Adhesion strength (gf/inch) measured 30 minutes after attaching to the target adherend surface at room temperature
A2: Adhesion strength (gf/inch) measured 1,000 hours after attaching to the target adherend surface at room temperature

After the variable adhesive layer (151) is attached to the target adherend surface of the intended installation object, the adhesion strength (A1) with respect to the adherend surface, measured 30 minutes later at room temperature, is 50 gf/in or less.

After the variable adhesive layer (151) is attached to the target adherend surface of the intended installation object, the adhesion strength (A1) with respect to the adherend surface, measured 1,000 hours later at room temperature, is more than 50 gf/in or less.

By satisfying an A-value of 1 or more according to Equation 2, the variable adhesive film (150) provides excellent wettability, re-peelability, and adhesive reliability with respect to the target adherend surface of the intended installation object. It can be attached without defects such as air bubbles, and it allows re-peelability on surfaces like plastic or glass, offering excellent peel strength and workability, and once fully adhered, it can prevent peeling, lifting, and other issues.

The base film (152) of the variable adhesive film (150) may include a polymer resin selected from a group consisting of polyethylene terephthalate (PET), polycarbonate (PC), polyethylene (PE), polyurethane (PU), polyimide (PI), cyclic olefin polymer (COP), polyethylene naphthalate (PEN), polyether sulfone (PES), polyether ether ketone (PEEK), polyphenylene sulfide (PPS), polyamide (PA), polycyclohexylene dimethylene terephthalate (PCT), and polypropylene (PP), or an alloy resin thereof, but is not limited to these. The thickness of the base film (152) may be from 50 to 150 μm, preferably 50 to 100 μm

The variable adhesive layer (151) of the variable adhesive film (150) may be manufactured from a pressure-sensitive adhesive composition, which includes a urethane resin composition containing a urethane-based resin as the main component, an interface control agent, and an adhesion promoter.

In one embodiment of the disclosure, the pressure-sensitive adhesive composition contains an interface control agent and adhesion promoter at a weight ratio (interface control agent/adhesion promoter) of 0.8 or less. When this range is met, the variable adhesive film (150) exhibits excellent wettability, re-peelability, and adhesive reliability with the target adherend surface of the intended installation object.

The variable adhesive layer (151) contains both the interface control agent and adhesion promoter, satisfying both re-peelability and attachment stability on the target adherend surfaces such as plastic or glass. The variable adhesive layer (151) produced from the pressure-sensitive adhesive composition initially has low adhesion and excellent re-peelability on the target adherend surface, as the interface control agent in the variable adhesive layer (151) is distributed and exists on the target adherend surface. Over time, however, a rearrangement of the interface control agent and the adhesion promoter occur, leading to increased interaction between the adhesion promoter and the target adherend surface, which enhances adhesion strength and provides attachment stability. Ultimately, this disclosure provides a light-emitting diode film (10) with excellent wettability, re-peelability, and adhesive reliability through the variable adhesive layer (151).

The variable adhesive film (150) may include a release film (200) on the variable adhesive layer (151) until it is attached to the target adherend surface of the intended installation object.

The release film (200) is hydrophobic to exhibit release properties with respect to the variable adhesive layer (151), while the target adherend surfaces of plastic or glass are more hydrophilic than the release film (200). Therefore, when the release film (200) on the variable adhesive layer (151) is removed, and the variable adhesive layer (151) is attached to the target adherend surface of the intended installation object, the hydrophobic groups of the interface control agent initially orient towards the adherend surface, resulting in low adhesion. However, over time, on adherend surfaces such as plastic or glass that are relatively more hydrophilic than the release film (200), a balance between the hydrophobic and hydrophilic groups of the interface control agent within the variable adhesive layer (151) is achieved, leading to a rearrangement. Eventually, the adhesion promoter interacts with the target adherend surface, resulting in an increase in adhesion strength.

Below, the urethane resin composition, interface control agent, and adhesion promoter that may be included in the variable adhesive layer (151) are described, though they are not limited to these.

### Urethane Resin Composition

The urethane resin composition mainly consists of a urethane resin obtained by curing a urethane prepolymer, which is formed by reacting a polyol with a multifunctional isocyanate compound in the presence of a catalyst.

The polyol may contain a single type of polyol, or preferably two or more types of polyol. One of these polyols should have three or more hydroxyl (OH) groups, examples of which include polyester polyol, polyether polyol, polycaprolactone polyol, polycarbonate polyol, and castor oil-based polyol. Due to these polyol components, it can exhibit excellent reworkability characteristics, such as reduced residue.

The polyester polyol can be obtained through an esterification reaction between a polyol component and an acid component. Examples of polyol components can be selected from a group consisting of ethylene glycol, diethylene glycol, 1,3-butanediol, 1,4-butanediol, neopentyl glycol, 3-methyl-1,5-pentanediol, 2-butyl-2-ethyl-1,3-propanediol, 2,4-diethyl-1,5-pentanediol, 1,2-hexanediol, 1,6-hexanediol, 1,8-octanediol, 1,9-nonanediol, 2-methyl-1,8-octanediol, 1,8-decanediol, octadecanediol, glycerin, trimethylolpropane, pentaerythritol, hexanetriol, and polypropylene glycol. Examples of acid component include succinic acid, methylsuccinic acid, adipic acid, pimelic acid, azelaic acid, sebacic acid, 1,12-dodecanedioic acid, 1,14-tetradecanedioic acid, dimer acid, 2-methyl-1,4-cyclohexanedicarboxylic acid, 2-ethyl-1,4-cyclohexanedicarboxylic acid, terephthalic acid, isophthalic acid, phthalic acid, 1,4-naphthalenedicarboxylic acid, 4,4′-biphenyldicarboxylic acid, and their anhydrides.

Additionally, polyether polyol is obtained by using water, low-molecular-weight polyols (such as propylene glycol, ethylene glycol, glycerin, trimethylolpropane, and pentaerythritol), bisphenols (such as bisphenol A), or dihydroxybenzenes (such as catechol, resorcinol, and hydroquinone) as initiators, followed by addition polymerization with an alkylene oxide selected from ethylene oxide, propylene oxide, or butylene oxide. Specific examples include polyethylene glycol, polypropylene glycol, and polytetramethylene glycol.

The polycaprolactone polyol is a caprolactone-based polyester diol obtained by the ring-opening polymerization of cyclic ester monomers such as F-caprolactone or a-valerolactone. Examples include olycarbonate polyols obtained by polycondensation reactions between the polyol components and phosgene; polycarbonate polyols obtained by ester exchange and condensation reactions between the polyol components and carbonic acid diesters such as dimethyl carbonate, diethyl carbonate, dipropyl carbonate, diisopropyl carbonate, dibutyl carbonate, ethyl butyl carbonate, ethylene carbonate, propylene carbonate, diphenyl carbonate, or dibenzyl carbonate; polycarbonate polyols obtained by copolymerization using two or more types of polyol components; polycarbonate polyols obtained by esterification reaction between the various types of polycarbonate polyols and carboxyl group-containing compounds; polycarbonate polyols obtained by etherification reaction between various types of polycarbonate polyols and hydroxyl group-containing compounds; polycarbonate polyols obtained by ester exchange reactions between the various types of polycarbonate polyols and ester compounds; polycarbonate polyols obtained by ester exchange reactions between the various types of polycarbonate polyols and hydroxy group-containing compounds; polycarbonate polyols obtained by copolymerizing the various types of polycarbonate polyols and dicarboxylic acid compounds; and polycarbonate polyols obtained by copolymerizing the various types of polycarbonate polyols and alkylene oxides to form polyether-based polycarbonate polyols.

The castor oil-based polyol is obtained by reacting castor oil fatty acids with the polyol component.

As another component for manufacturing the urethane resin, a multifunctional isocyanate compound may be used, which can be selected from aliphatic, cycloaliphatic, and aromatic multifunctional diisocyanate compounds, or a trimer with an isocyanurate ring, either alone or in a mixture.

Examples of preferred aliphatic multifunctional isocyanate compounds include trimethylene diisocyanate, tetramethylene diisocyanate, hexamethylene diisocyanate, 1,2-propylene diisocyanate, 1,3-butylene diisocyanate, dodecamethylene diisocyanate, and 2,4,4-trimethylhexamethylene diisocyanate.

Examples of cycloaliphatic multifunctional isocyanate compounds include 1,3-cyclopentane diisocyanate, 1,3-cyclohexane diisocyanate, 1,4-cyclohexane diisocyanate, isophorone diisocyanate, hydrogenated diphenylmethane diisocyanate, hydrogenated xylylene diisocyanate, hydrogenated tolylene diisocyanate, and hydrogenated tetramethylxylylene diisocyanate. Examples of aromatic multifunctional diisocyanate compounds include phenylene diisocyanate, 2,4-tolylene diisocyanate, 2,6-tolylene diisocyanate, 2,2′-diphenylmethane diisocyanate, 4,4′-diphenylmethane diisocyanate, 4,4′-toluidine diisocyanate, 4,4′-diphenyl ether diisocyanate, 4,4′-diphenyl diisocyanate, 1,5-naphthalene diisocyanate, and xylylene diisocyanate.

A urethane prepolymer with terminal hydroxyl groups can be produced by reacting the polyol and multifunctional isocyanate compound in the presence of a catalyst, and then a multifunctional isocyanate compound with two or more functional groups can be used as a curing agent to form a three-dimensional network structure.

Another example of a multifunctional isocyanate compound includes trimethylolpropane adducts of various multifunctional isocyanate compounds mentioned above, biurets obtained by reacting with water, and trimers with isocyanurate rings. These can be used alone or in combination.

As described above, the urethane resin is obtained by curing a composition containing a polyol and a multifunctional isocyanate compound. This composition may include antistatic agents, catalysts, other resin components aside from the urethane resin, adhesion boosters, inorganic fillers, organic fillers, metal powders, pigments, softening agents, plasticizers, anti-aging agents, conductive agents, antioxidants, UV absorbers, light stabilizers, surface lubricants, leveling agents, corrosion inhibitors, heat stabilizers, polymerization inhibitors, lubricants, solvents, etc., as long as they do not impair the effects of present disclosure. Preferably, it may also include degradation inhibitors, such as antistatic agents, antioxidants, UV absorbers, or light stabilizers.

### <Interface Control Agent>

An interface control agent is a compound that has both hydrophilic (water-soluble) and hydrophobic (oil-soluble) groups within a single molecule. Hydrophilicity refers to the tendency to bond with water molecules, while hydrophobicity describes a property that is less compatible with water.

In this disclosure, a silicone-based nonionic interface control agent may be used as an interface control agent.

The silicone-based nonionic agent may be at least one selected from a modified polydimethylsiloxane (for example, alkyl-modified, phenyl-modified, amino-modified, polyether-modified, or polyoxyalkylene-modified polydimethylsiloxane), organosilicone, polyalkylene-modified heptamethyltrisiloxane, polyalkylene oxide-modified dimethylpolysiloxane, polyalkylene oxide-modified heptamethyltrisiloxane, polyalkylene oxide-modified heptamethylsiloxane, polyether-polymethylsiloxane copolymer, polyethoxylated dimethyl siloxanes, polymethylsiloxane copolymer, polyoxypropylene-polyoxyethylene block copolymer, or silicone-polyether copolymer, but it is not limited thereto. In a preferred embodiment, the silicone-based nonionic interface control agent may be a polyalkylene oxide-modified silicone, in which polar polyethylene oxide/polypropylene oxide blocks are grafted onto the silicone backbone, such as polyethylene oxide-modified dimethylpolysiloxane or polypropylene oxide-modified dimethylpolysiloxane. It may preferably be a polyalkylene oxide-modified silicone containing polyethylene oxide and polypropylene oxide, with the ends of the polyethylene oxide and polypropylene oxide capped with alkyl groups such as methyl or butyl. If the ends of the polyethylene oxide and polypropylene oxide are not capped with alkyl groups, hydroxyl groups generated through reactions may chemically interact with the urethane resin in the adhesive, thereby interfering with the rearrangement of the interface control agent toward the target adherend surface.

The silicone-based nonionic interface control agent is preferably used in an amount from 0.01 to 5 parts by weight per 100 parts by weight of urethane resin. If included in an amount less than 0.01 parts by weight, the amount of the interface control agent in the adhesive interface in contact with the release film (200) may be insufficient, resulting in increased adhesion strength and decreased reworkability. If more than 5 parts by weight are included, the excessive amount of the interface control agent on the adhesive surface may delay the rearrangement to reach equilibrium, preventing an increase in adhesion strength and resulting in reduced adhesion reliability. The silicone-based nonionic interface control agent has a Hydrophilic-Lipophilic Balance (HLB) value of 4 to 8. When the HLB value is in this range, the hydrophilic group of the interface control agent gradually aligns toward the target adherend surface over time, leading to a gradual increase in adhesion strength. If the HLB value is less than 4, the interface control agent is too hydrophobic, making it difficult for reorientation toward the target adherend surface and preventing an increase in adhesion strength. Conversely, if the HLB value is more than 8, it is too hydrophilic, preventing rearrangement within the adhesive, leading to a lack of increased adhesion strength and weak adhesion strength.

### <Adhesion Promoter>

In this disclosure, a silane coupling agent may be used as an adhesion promoter. Examples of adhesion promoter include vinyltrimethoxysilane, vinyltriethoxysilane, 3-glycidoxypropyltrimethoxysilane, 3-glycidoxypropylmethyldiethoxysilane, 3-glycidoxypropyltriethoxysilane, 2-(3,4-epoxycyclohexyl)ethyltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, 3-acryloxypropylmethyldimethoxysilane, 3-chloropropyltrimethoxysilane, 3-mercaptopropylmethyldimethoxysilane, 3-mercaptopropyltriethoxysilane, etc.

The adhesion promoter is preferably used in an amount from 0.1 to 10 parts by weight per 100 parts by weight of urethane resin. If the adhesion promoter is included in an amount less than 0.1 parts by weight, an increase in adhesion strength may not occur after attachment to the adhesion surface, leading to low adhesion reliability. If the adhesion promoter is included in an amount more than 10 parts by weight, detachment after a certain period may lead to issues such as damage to the target object and the presence of adhesive residue.

In one embodiment of present disclosure, the composition includes a weight ratio (a/b) of the interface control agent (a) to the adhesion promoter (b) of 0.8 or less. Preferably, the weight ratio is 0.7 or less, and even more preferably 0.5 or less. If the ratio is more than 0.8, adhesion strength may not increase over time, significantly reducing adhesion reliability.

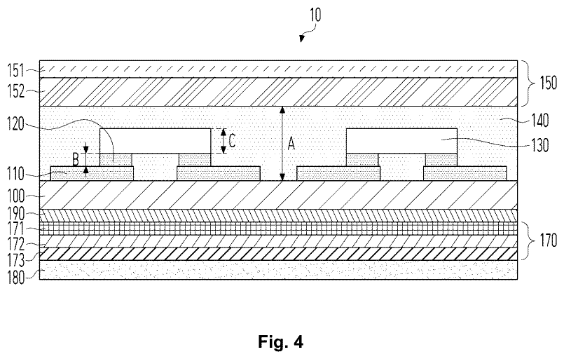

In one embodiment of this disclosure, the light-emitting diode film (10) includes a substrate (100); an electrode layer (110) formed on at least a part of the substrate (100); solder (120) formed on at least a portion of the electrode layer (110); a light-emitting diode (130) located on the solder (120) and connected to the electrode layer (110); a molding layer (140) applied to the entire surface of the substrate (100), electrode layer (110), and light-emitting diode (130); and a variable adhesive film (150) positioned on the molding layer (140). Furthermore, a protective film (170) may be included on the lower part of the substrate (100), opposite the side where the electrode layer (110) is formed (see FIG. 4). The protective film (170) serves to protect the physical integrity of the light-emitting diode film (10) from external impacts.

In one embodiment of this disclosure, the protective film (170) is positioned on the lower side of the substrate (100) where the electrode layer (110) is formed. For example, the protective film (170) may be positioned directly on the lower part of the substrate (100) or may have other components between the substrate (100) and the protective film (170).

In one embodiment of this disclosure, the protective film (170) may include an adhesive layer (171), a base layer (172), and a protective coating layer (173). In this case, the adhesive layer (171) is positioned to face the substrate, and the protective coating layer (173) is positioned at the outermost part of the lower part of the substrate in the final Light-emitting diode film (10) product.

In one embodiment of this disclosure, only the protective coating layer (173) is attached to the lower side of the substrate, opposite the side where the electrode layer is formed. The protective coating layer (173) may be positioned directly under the substrate (100) or may have other components between the substrate (100) and the protective coating layer (173)

In one embodiment of this disclosure, the adhesive layer (171) and protective coating layer (173) can be made by using adhesive compositions prepared with proper base resins such as acrylic resin, epoxy resin, urethane resin, ester resin, etc. However, they are not limited to these and can be prepared with commonly used adhesive compositions.

At least one layer within the protective film (170)—such as the adhesive layer (171), base layer (172), and protective coating layer (173)—may include commonly used additives in addition to the base resin. For example, these layers can have light-absorbing, light-blocking, or light-scattering materials, which provide respective functions of light-absorbing, light-blocking, or light-scattering.

The protective coating layer (173) may include commonly added additives in addition to the listed resins, as long as they do not impair the effects of this disclosure. For example, it may include light-absorbing, light-blocking, and/or light-scattering materials, thereby providing light absorption, light blocking, and/or light scattering functions.

In another embodiment of this disclosure, the substrate (100) may have light-absorbing, light-blocking, or light-scattering functions. Additionally, or alternatively, at least one layer within the variable adhesive film (150), such as the base film (152) and/or the variable adhesive layer (151), may also possess light-absorbing, light-blocking, or light-scattering functions. In this case, the transmittance of the variable adhesive film may be from 30% to 80%.

In this disclosure, if at least one layer of the light-emitting diode film (10) includes light-absorbing, light-blocking, or light-scattering functions, commonly used materials for these functions may be added to those layers.

In one embodiment of this disclosure, a contrast-enhancing layer (190) may be located directly beneath the opposite side of the substrate (100) where the electrode layer (110) is formed to improve the contrast ratio of the light-emitting diode film (10). The contrast-enhancing layer (190) may be formed by applying and drying a black resin composition containing a light-absorbing material such as carbon black to the substrate, and it may exist in the form of a sheet, plate, or film. Light-absorbing materials such as carbon black, titanium black (e.g., lower oxide titanium or titanium oxynitride), metal oxides such as iron oxide and other mixed organic pigments may be used.

The contrast-enhancing layer (190) has an opaque or semi-transparent optical property due to its black or colored appearance. The contrast-enhancing layer (190) may have patterns according to transmittance, providing an LED with improved optical properties. For example, the black resin composition can be applied and dried on the substrate to form a black coating layer, and photolithography can then be used to provide a fine patterning of the contrast enhancement layer (190).

As shown in FIG. 4, in one embodiment of this disclosure, a construction protective film (180) is included on the lowest part of the substrate (100) to prevent product damage during processing, and is removed after the manufacturing process.

In this disclosure, the yellow index (b*) of the Light-emitting diode film (10) should remain at or below Δ5 after a light resistance test. If the yellow index is more than Δ5, the film's overall transparency diminishes. Therefore, maintaining a yellow index (b*) of Δ5 or less ensures high transparency and visible light transmittance, along with achieving the desired neutral color and excellent light resistance properties.

The following describes the structure and operation of this disclosure in greater detail through preferred embodiments. However, these embodiments are provided solely to aid in understanding the disclosure and are not intended to limit the scope of this disclosure.

### Preparation for the LED Film

A transparent mesh electrode substrate, constructed from a laminated Ni-Cu structure on a 188 μm PET film, was prepared. Solder paste was printed onto terminal portions of the substrate, followed by LED mounting using a chip mounting device, and subjected to reflow processing to reach a peak temperature of 180° C.

Afterward, the molding liquid was prepared according to the specifications in each example and applied onto the film-type LED substrate. For all examples except Comparative Example 7, a variable adhesive layer of variable adhesion film was applied to face and adhere to the molding layer. UV curing was then conducted to solidify the molding layer, producing the final LED film.

### Preparation for the Variable Adhesion Film

The variable adhesive composition was prepared by combining 100 parts by weight of urethane prepolymer containing terminal hydroxyl groups (molecular weight 80,000) with 6 parts by weight of multifunctional hexamethylene diisocyanate as a crosslinking agent and adding 0.01 parts of a catalyst (DBTDL), 0.3 parts of polypropylene oxide/polyethylene oxide (20/80) polydimethylsiloxane with an HBL of 7, and 2 parts by weight of 3-methacryloylpropyltrimethoxysilane and diluting with methyl ethyl ketone (MEK) to achieve a solid content of 50% by weight, followed by mixing and degassing. The prepared variable adhesive composition was then applied onto a PET substrate film and dried in a 120° C. oven for 3 minutes to form an adhesive layer with a thickness of 100 μm.”

### Preparation for Molding Liquid

Example 1: A molding liquid was prepared by homogenizing 30 g of urethane acrylate oligomer SC2404 (MIWON), 20 g of isobornyl acrylate, 40 g of ethylhexyl acrylate, 10 g of trimethylolpropane triacrylate, and 1 g of Irgacure 651.

Using the prepared molding liquid, an LED film was obtained following the method previously described. In this example, the thickness (A) of the molding layer was set to be 1.5 times the combined height of the solder thickness (B) and the LED thickness (C).

Example 2: A molding liquid was prepared by homogenizing 20 g of polyisobutylene (BASF OPPANOL B15N), 50 g of isobornyl acrylate, 15 g of 2-ethylhexyl acrylate, 15 g of tricyclodecane dimethanol diacrylate, and Ig of Irgacure 651. Except for preparing the molding liquid through homogenization as described, an LED film was obtained following the procedure outlined in Example 1.

Example 3: An LED film was obtained following the method of Example 1, except that a basket mill was used to disperse 3 g of zirconia (ZrO₂) with an average particle diameter of 1 μm in the molding liquid of Example 1 to include a scattering agent in the molding liquid.

Example 4: An LED film was obtained following the method of Example 1, except that a basket mill was used to disperse 0.5 g of carbon black with an average particle diameter of 25 nm in the molding liquid of Example 1 to include particles capable of controlling transmittance agent in the molding liquid.

Comparative Example 1: An LED film was obtained following the method of Example 1, except that the thickness (A) of the molding layer was set to 0.8 times the combined height of the solder thickness (B) and the LED thickness (C).

Comparative Example 2: An LED film was obtained following the method of Example 1, except that the thickness (A) of the molding layer was set to 5.2 times the combined height of the solder thickness (B) and the LED thickness (C).

Comparative Example 3: A molding liquid was prepared by homogenizing 10 g of urethane acrylate oligomer SC2404 (Miwon), 10 g of isobornyl acrylate, 75 g of ethylhexyl acrylate, 5 g of trimethylolpropane triacrylate, and 1 gram of Irgacure 651. Using the prepared molding liquid, an LED film was obtained following the method previously described. In this example, the thickness (A) of the molding layer was set to be 0.8 times the combined height of the solder thickness (B) and the LED thickness (C).

Comparative Example 4: An LED film was obtained following the method of Comparative Example 3, except that the thickness (A) of the molding layer was set to 5.2 times the combined height of the solder thickness (B) and the LED thickness (C).

Comparative Example 5: A molding liquid was prepared by homogenizing 40 g of urethane acrylate oligomer SC2404 (Miwon), 30 g of isobornyl acrylate, 10 g of ethylhexyl acrylate, 20 g of trimethylolpropane triacrylate, and 1 gram of Irgacure 651. Using the prepared molding liquid, an LED film was obtained following the method previously described. In this example, the thickness (A) of the molding layer was set to be 0.8 times the combined height of the solder thickness (B) and the LED thickness (C).

Comparative Example 6: An LED film was obtained following the method of Comparative Example 5, except that the thickness (A) of the molding layer was set to 5.2 times the combined height of the solder thickness (B) and the LED thickness (C).

Comparative Example 7: An LED film was obtained following the method of Example 1, except that a PET release film was applied to the molding layer instead of a variable adhesion film.

### Experimental Example: Performance Evaluation of LED Film

The performance of transparent LED film panels, produced in each Example and Comparative Example, was evaluated using the following methods.

### 1. Shrinkage Rate Measurement

After applying the molding liquid prepared each Example and Comparative Example, the density of the liquid molding solution (before UV curing) and the solidified molding layer (after UV curing) was measured. The curing shrinkage rate was then calculated using the following formula:

Shrinkage Rate of Molding Liquid=(1/Density after curing−1/Density before curing)/(1/Density before curing)×100

### 2. Tensile Strength (Young's Modulus and Elongation)

The molding liquid prepared in the examples and comparative examples was applied and cured to obtain a molding layer with a thickness of 1.3 mm. The molding layer sample was cut to a length of 60 mm and a width of 15 mm. The cut specimen was fixed with a distance of 25 mm between the upper and lower jigs of a universal testing machine (UTM). The specimen was then subjected to tensile testing at a speed of 100 mm/min, Young's modulus was calculated by measuring the stress relative to strain until the specimen fractured.

Young's modulus (E′): Defined as the ratio of stress to strain in the range of 0.3% to 1% strain.

$$E = \frac{σ}{ε}$$

E: Young's modulus.
σ: Uniaxial stress, or uniaxial force per unit area.
ϵ: Strain, representing the change in length divided by the original length, which is a dimensionless value

### 3. Total Light Transmittance and Haze Measurement

The total light transmittance of the molding layer prepared in the examples and comparative examples was measured within the range of 380 to 760 nm according to JIS K 7105 standards, and haze was measured using the NDH-7000 (Nippon Denshoku Co.).

### 4. Push Test

The variable adhesive films of the LED films, prepared in Examples 1 through 4 and Comparative Examples 1 through 6, was attached to a glass or SUS plate, ensuring that the transparent substrate was positioned on the top layer. In the case of Comparative Example 7, the detached molding layer of the LED film was adhered to the glass or SUS plate, ensuring the transparent substrate was positioned on the top. The LED film was then powered to emit light from the LED. Using a 5 mm diameter probe with a Push Pull Gauge, pressure was applied to each LED point, and the force required to dislodge the LED was measured. The standard for acceptable quality was set at 3 Kgf.

### 5. Adhesion Performance

The prepared LED films in both the examples and comparative examples were cut to a size of 430×600 mm, and attached to the surface of a glass substrate using a wool applicator to avoid bubble formation. The adhesion performance of each example was evaluated based on the following criteria:

### Good (O):

No trapped bubbles formed, and no edge lifting occurred after attachment.
Demonstrated excellent performance during repositioning, allowing for re-peeling and reattachment

### Defective (X):

Bubbles formed and were trapped.
Poor re-peeling and reattachment performance for repositioning.

TABLE 1

| | | | | | Compar- | Compar- | Compar- | Compar- | Compar- | Compar- | Compar- |
|---|---|---|---|---|---|---|---|---|---|---|---|
| | | | | | ative | ative | ative | ative | ative | ative | ative |
| | Example 1 | Example 2 | Example 3 | Example 4 | Example 1 | Example 2 | Example 3 | Example 4 | Example 5 | Example 6 | Example 7 |
| Molding | 8 | 7 | 7 | 7 | 8 | 8 | 4 | 4 | 15 | 15 | 8 |
| Layer | | | | | | | | | | | |
| Curing | | | | | | | | | | | |
| Shrinkage | | | | | | | | | | | |
| rate | | | | | | | | | | | |
| (%) | | | | | | | | | | | |
| Molding | 0.7 | 0.55 | 0.72 | 0.69 | 0.7 | 0.7 | 0.03 | 0.03 | 120 | 120 | 0.7 |
| Layer | | | | | | | | | | | |
| Young's | | | | | | | | | | | |
| Modulus (MPa) | | | | | | | | | | | |
| Total Light | 91 | 93 | 88 | 70 | 91 | 91 | 91 | 90 | 90 | 88 | 91 |
| Transmittance | | | | | | | | | | | |
| (Tt, %) | | | | | | | | | | | |
| Haze (%) | 0.8 | 0.6 | 20 | 2 | 0.8 | 0.8 | 0.6 | 0.9 | 0.8 | 1.1 | 0.8 |
| Push Test | 10.5 | 8 | 10.5 | 10 | 13 | 2.5 | 8 | 1.1 | 13 | 11 | 12 |
| (Kgf) | | | | | | | | | | | |
| Adhesion | ◯ | ◯ | ◯ | ◯ | X | X | X | X | X | X | X |
| performance | | | | | | | | | | | |
| durability | ◯ | ◯ | ◯ | ◯ | X | ◯ | X | X | X | ◯ | ◯ |

As shown in Table 1, Examples 1 to 4 all exhibited favorable adhesion performance and durability properties.

In contrast, Comparative Examples 1 to 6 did not satisfy the following equation. (Equation 1: 1*(B+C)≤A≤5*(B+C), where A is the height of the molding layer measured from the substrate, B is the thickness of the solder, and C is the thickness of the light-emitting diode)

Consequently, in Comparative Example 1, air bubbles became trapped during the lamination of the variable adhesive film, resulting in lifting. Additionally, the uniformity and flatness of the molding layer and variable adhesive film corresponding to the location of the LED chip were suboptimal. Therefore, the adhesion performance was not favorable, and the durability of the LED was affected. In Comparative Example 2, the molding layer did not satisfy Equation 1: 1*(B+C)≤A≤5*(B+C), where A is the height of the molding layer measured from the substrate, B is the thickness of the solder, and C is the thickness of the light-emitting diode. As a result, cracks in the wiring occurred even at a low force of 2.5 kgf during the push test, and the molding layer warped, causing poor adhesion due to lifting. Furthermore, the push test results indicated a durability of less than 3 kgf, demonstrating insufficient durability.

For Comparative Examples 3 and 4, the adhesion performance was suboptimal, and the Young's modulus of the molding layer was measured at 0.03, below the threshold of 0.05. Notably, Comparative Example 4 had a very low push test value of 1.1 kgf, indicating that external forces like impact, pressure, or bending could damage wiring, solder, and LEDs, resulting in poor durability.

In Comparative Examples 5 and 6, the curing shrinkage rate of the molding layer was measured at 15%, with a Young's modulus of 120 MPa, indicating reduced flexibility, stretchability, and adhesion properties. High Young's modulus, as seen in Comparative Examples 5 and 6, leads to a shrinkage rate exceeding 10-13%. In these cases, when the LED film is attached to the target surface, even a slight curl formation results in lifting, thus reducing adhesion performance.

Finally, in Comparative Example 7, which did not include a variable adhesive film, the re-attachment adhesive strength and, consequently, adhesion performance were insufficient.

### REFERENCE NUMERALS

10: LED Film
20: Target Installation Object
100: Substrate
110: Electrode Layer
120: Solder
130: LED
140: Molding Layer
150: Variable Adhesive Film
151: Variable Adhesive Layer
152: Base Film
200: Release Film
170: Protective Film
171: Adhesive Layer
172: Base Layer
173: Protective Coating Layer
180: Installation Protective Film
190: construction protective film
A: Height of the Molding Layer
B: Height of the Solder
C: Thickness of the LED

1. A substrate;
an electrode layer formed on at least a portion of the substrate;
solder formed on at least a portion of the electrode layer;
a light-emitting diode (LED) positioned on the solder and connected to the electrode layer;
a molding layer applied to cover the entire surface of the substrate, electrode layer, and LED; and
a variable adhesive film located on the molding layer,
wherein the LED film satisfies the following Equation 1:
$$1 * ( B + C ) \leq A \leq 5 * ( B + C ) \qquad [ Equation 1 ]$$
where A represents the height of the molding layer measured from the substrate, B represents the thickness of the solder, and C represents the thickness of the LED.

2. The LED film according to claim 1, wherein the molding layer has an adhesive strength of 100 gf/cm or more with respect to each of the substrate and the variable adhesive film.

3. The LED film according to claim 1, wherein the Young's modulus of the molding layer is 0.05 to 50 MPa.

4. The LED film according to claim 1, wherein the molding layer is formed by curing a solvent-free molding liquid with UV.

5. The LED film according to claim 4, wherein the curing shrinkage rate of the cured molding liquid is 13% or less.

6. The LED film according to claim 4, wherein the viscosity of the molding liquid is from 100 cps to 2,000 cps.

7. The LED film according to claim 4, wherein the molding liquid includes at least one oligomer or polymer selected from silicone acrylate, acrylate, urethane acrylate, urethane, butylene, isobutylene and rubber; and oligomer or polymer selected from derivatives thereof, and UV initiators; and additives.

8. The LED film according to claim 7, wherein the molding liquid further includes inorganic scattering particles, organic scattering particles, light-absorbing particles, or combinations thereof.

9. The LED film according to claim 1, wherein the variable adhesive film includes a base film and a variable adhesive layer on the base film, and the base film is positioned directly on the molding layer, and the variable adhesive layer is attached to a target adherend surface of the intended installation object.

10. The LED film according to claim 9, wherein the variable adhesive layer has an adhesion value (A) of 1 or more with respect to the target adherend surface, defined by the following Equation 2:
A=(A2−A1)/A1 Where: [Equation 2]
A1 is the adhesion strength (gf/inch) measured 30 minutes after attaching to the target adherend surface at room temperature, and
A2 is the adhesion strength (gf/inch) measured 1,000 hours after attaching to the target adherend surface at room temperature.

11. The LED film according to claim 10, wherein the adhesion strength (A1) of the variable adhesive layer with respect to the target adherend surface is 50 gf/in or less.

12. The LED film according to claim 10, wherein the adhesion strength (A2) of the variable adhesive layer with respect to the target adherend surface may is more than 50 gf/in.

13. The LED film according to claim 9, wherein the thickness of the variable adhesive layer is 50 to 150 μm.

14. The LED film according to claim 1, wherein a protective film or protective coating layer is further included on the lower part of the substrate opposite to the side on which the electrode layer is formed.

15. The LED film according to claim 14, wherein the protective film includes an adhesive layer, a base layer, and a protective coating layer, with the adhesive layer positioned facing the substrate.

16. The LED film according to claim 14, wherein the protective coating layer may have light-absorbing, light-blocking, or light-scattering function.

17. The LED film according to claim 15, wherein at least one layer of the adhesive layer, base layer, and protective coating layer has light-absorbing, light-blocking, or light-scattering function.

18. The LED film according to claim 1, including a contrast-enhancing layer directly beneath the opposite side of the substrate on which the electrode layer is formed.

19. The LED film according to claim 1, including a construction protective film on the lowest part of the substrate.

20. The LED film according to claim 1, wherein the yellow index (b*) after a light resistance test is Δ5 or less.
